(19) United States
(12) Patent Application Publication
(10) Pub. No.: US 2015/0110222 A1
(43) Pub. Date: Apr. 23, 2015

(54) SYSTEM AND METHOD FOR AMPLIFYING A SIGNAL

(71) Applicant: THALES, NEUILLY SUR SEINE (FR)

(72) Inventors: Jessica BOUVIER, GENNEVILLIERS (FR); Bruno COSTA, GENNEVILLIERS (FR); Pierre GUERN, GENNEVILLIERS (FR)

(21) Appl. No.: 14/516,358

(22) Filed: Oct. 16, 2014

(30) Foreign Application Priority Data
Oct. 18, 2013 (FR) 13 02416

(51) Int. Cl. H04L 25/02; H03G 3/20; H04L 27/00

(52) U.S. Cl. CPC H04L 25/028; H04L 27/0002; H03G 3/20
USPC 375/297

(57) ABSTRACT

An amplification system, connected to a modem delivering a signal to be amplified, includes at least one amplification device, at least one first determination device for determination of a first difference and at least one second determination device for determination of a variable gain. Moreover, the system is characterized in that the second determination device is capable of the determination of said variable gain on the basis of said signal to be amplified, said amplified signal and said first difference.

### CROSS-REFERENCE TO RELATED APPLICATION

This application claims priority to foreign French patent application No. FR 1302416, filed on Oct. 18, 2013, the disclosure of which is incorporated by reference in its entirety.

### FIELD OF THE INVENTION

The present invention concerns an amplification system having a servo-control device for the transmission power. These systems can be used in civil or military radio communications equipment, for example, using waveforms that have a non-constant envelope and that can be single-carrier or multi-carrier.

### BACKGROUND

It is known that the use of this type of waveform necessitates making an allowance on the output power of the power amplifier (this allowance is likewise known by the expression Output Back-Off). The aim of this allowance is to remain within a region of linear operation of the power amplifier. However, the presence of this allowance is inconsistent with the quest for the best possible yield. The reason is that in order to improve the yield of the power transistors used in radio communications equipment, they are often focussed into class AB. One of the special features of the AB class is that its yield increases when the transmitted power increases. Another special feature of this class of operation is that its optimum operating point in terms of linearity is dependent on a certain number of operating variables such as the transmission frequency used or the temperature. These special features make it necessary to look for a compromise between yield and linearity for each waveform.

In order to solve this problem, devices that have an automatic power control loop (likewise known by the expressions ALC for Automatic Level Control) are known from the prior art.

Systems that use open-looped servo-control on the basis of a conversion table are known from the prior art. This table is produced in the factory, during production of the radio, and may possibly have an update mechanism. Thus, in these systems, the control of the transmission power will be dependent not on the signal at the output of the amplifier, but only on the signal at the input of the amplifier. These systems are very sensitive to the load variation of the antenna in a mobility situation and necessitate long calibration times, reducing the production capacities of the modules.

Systems operating in closed-looped mode are also known from the prior art. These systems are shown in FIG. 1, are connected to a modem 101 and have an amplification device 102 exhibiting a variable amplification gain. They also have a device 103 for determining a difference between the amplified signal and a copy of the signal to be amplified. Finally, these systems have a device 104 for determining the amplification gain on the basis of the difference.

The device 103 for determining a difference is known to carry out filtering of the amplified signal or of the signal representing the difference so as to remove the contribution of the variations in the modulation envelope on the gain control signal. The automatic gain control is then severely slowed down in relation to the spread band for the frequencies of the modulation used. In general, the loop band must be one hundred times lower than the bandwidth of the modulation in order to completely eliminate envelope variations. Thus, the patents U.S. Pat. Nos. 7,023,278 B1 (Rockwell Collins, 2006) and U.S. Pat. No. 6,735,420 B2 (Globespan Virata, 2001) exhibit systems that use this solution. This type of system therefore cannot be used for amplifying signals that exhibit rapid variations in the modulation frequency (these signals are also known by the expression FH for Frequency Hopping) and that exhibit modulation in which the envelope is not constant. The reason is that these systems differentiate between an unmodulated setpoint signal and a modulated return signal, the effect of which is to create perturbations on the error signal that translate into a high level of imprecision on the variable gain control. During FH operation, this system is unacceptable because it does not have time to converge in a single transmission time interval on account of the need for the filtering to be very extensive.

The device 103 for determining a difference is known to make direct use of the samples of the signal to be amplified as a setpoint. It this case, the gain control loop can be rapid and it is possible to eliminate the envelope variations of the gain control signal. Thus, the patents U.S. Pat. No. 7,353,006 B2 (Analog Devices, 2004) and U.S. Pat. No. 7,773,691 B2 (RF Micro devices, 2005) exhibit systems that use this solution. In these systems, it is possible to eliminate envelope variations subject to the group propagation time of the transmission chain not being too long, otherwise this likewise translates into a perturbation on the error signal and imprecision on the variable gain control.

The use is also known, to improve the performance of the automatic control, in which the device 104 for determining the amplification gain can take account of the perturbations of the signal that are generated by the amplification device 102. However, in the prior art systems, this taking-account of the perturbations is static, that is to say that it does not use an estimator to update the model of the perturbations of the amplification device. Thus, these systems can cause instability if the gain and the delay of the radio channel differ from the expected values.

### SUMMARY OF THE INVENTION

The present invention therefore aims to overcome these problems by proposing an amplification system that is connected to a modem delivering a signal to be amplified. This system has at least one amplification device in which an amplification gain is variable. It also has at least one first determination device for determination of a first difference between an amplified signal and the signal to be amplified. Moreover, this system has at least one second determination device for determination of the variable gain. Moreover, the second determination device is capable of the determination of said variable gain on the basis of said signal to be amplified, said amplified signal and said first difference. This second device has at least one third determination device for determination of a model of the perturbation of the first difference by said amplification device on the basis of said signal to be amplified and said amplified signal. This second device also has at least one fourth determination device for determination of perturbations of the first difference, which are caused by said amplification device, on the basis of said model and said signal to be amplified. The second device also has at least one fifth determination device for determination of a second difference between said first difference and said perturbations and a controller that is capable of determining said variable gain on the basis of said second difference.

In one embodiment, the amplification system has at least one extraction device, for extraction of the amplified signal to the first determination device. This extraction device comprises a directional coupler that is used to recover the signal transmitted on a wire connecting the amplification device and an antenna. It also has at least one device for regulating the gain of the recovered signal. It then has a mixer for mixing the signal that has had its gain regulated with a sinusoidal signal. This coupler also has a plurality of filters for filtering the mixed signal, these filters comprising at least one fixed-bandwidth analogue filter that is used for anti-aliasing and/or anti-jamming and at least one switchable digital filter for the bandwidth that varies as a function of a bandwidth of said signal to be amplified and/or of a disparity between a frequency of said signal to be amplified and a frequency of said perturbations.

In one embodiment, the first determination device is connected directly to the modem.

In one embodiment, the model of the perturbations comprises a delay and a gain and the third determination device for determination of a model is capable of the determination of said model by means of a correlation between said signal to be amplified and said amplified signal.

In one embodiment, the controller is a PID controller.

In one embodiment, the second determination device has a conversion table relating a power of said signal to be transmitted to the amplification gain.

The present invention also proposes a method for using the amplification system having the following successive steps:
a step of configuration of the gain of said amplification device, said step of configuration being carried out when said signal to be amplified has zero power,
a step of increase of the amplification gain of the amplification device, in an initialization phase, during which said signal to be amplified does not have any useful data, and
a step of deactivation of the regulation of the gain, said step of deactivation being carried out when the signal to be amplified has useful data.

In one embodiment, the method has a step of regulation of the amplification gain of the amplification device. This step of regulation of the amplification gain is carried out after the step of increase of the amplification gain. Moreover, this step of regulation is carried out on the basis of a setpoint.

In one embodiment, the step of configuration is suited to the implementation of the relationship

Pout_max=Pout_mean_MODEM_setpoint+Modulation_crest_factor

where;
Pout_max represents the maximum output power in dBm,
Pout_mean_MODEM_setpoint represents the mean power in dBm of the signal that said modem (101) will transmit, and
Modulation_crest_factor represents the modulation crest factor in dB of the signal that will be transmitted by said modem (101).

Moreover, the step of configuration is suited to configuring the amplification device so as to be able to transmit a maximum output power of Pout_max.

The determination of Pout_max by means of this calculation allows configuration of the gain to be applied to the setpoint signal (setpoint gain) so as to compare it with the signal received on the measurement path.

On the basis of the value of Pout_max, calibration tables for the measurement path and for the transmission path are addressed. They contain the values of the setpoint gain and the configuration on the variable-gain elements of the measurement path and of the transmission path corresponding a priori to the power Pout_max.

In one embodiment, the step of increase of the amplification gain is implemented by means of a conversion table relating a power of said signal to be transmitted to said amplification gain when the power of said signal to be amplified is lower than a threshold; and by means of the controller when the power of said signal to be amplified is higher than said threshold.

Thus, the system and the method described in the invention provide the following advantages:

The delay in the main loop, which is caused by the filters of the amplification system that are necessary for co-site operation, is eliminated from the gain error (first difference) by virtue of the estimator of the model of perturbation of the signal by the amplification system.

Co-site operation is implemented when various radio systems are situated in a close geographical region. This geographical region is defined by a circle having a radius in the order of ten or so metres.

Moreover, the modelling of the signal as perturbed by the amplification system and the use of the modulated samples as a reference for the calculation of the first difference make it possible to significantly increase the bandwidth of the main loop and to make it independent of the bandwidth of the signal to be amplified. The bandwidth of the loop can then be chosen solely in order to comply with the rise time required by the waveform (in the case of waveform regularly changing transmission frequency, also known by the expression FH waveform). The loop bandwidth characterizes the behaviour of the system in closed-looped mode. It is calculated on the basis of the closed-looped transfer function of the system.

This transfer function in the case of this invention includes the contribution of all the filters of the transmission path and of the measurement path (when likened to their transfer function) and the transfer function of the controller.

If A(p) is the transfer function of the transmission chain associated with the controller and B(p) is the function of the chain of the measurement path. The closed loop transfer function (also known by the acronym CLTF) has the following value:

$$CLTF = \frac{A ( p )}{1 + A ( p ) * B ( p )}$$

The estimator of the perturbation of the signal caused by the amplification device allows optimum and stable gain control to be obtained, which makes it possible to control gain continuously, including during phases containing useful data and for waveforms with a non-constant envelope.

It is a servo-control system that allows a very significant reduction in the number of calibration tables, for the radio-frequency portion of the system, that it is necessary to determine at the moment of implementation of the system.

In non-servo-control systems, the precision of the transmitted power depends on the precision of calibration of the transmission path. The transmission path has a large number of non-linear elements (amplifiers, tuneable filters, etc.). Its gain is therefore greatly dependent on transmission power, temperature and frequency. It is therefore necessary to perform calibration over the entire range of operation that the radio station can cover.

The precision of the system of the invention is solely dependent on the precision of the calibration of the measurement path. Since the measurement path does not have any non-linear elements, it is easier and faster to calibrate than the transmission path.

The first determination device 103 connected directly to said modem 101 allows direct use of the samples from the modem to perform gain control.

Since the system implements devices for determining the perturbations of the signal to be amplified associated with an estimator of the model of the perturbations caused by the amplification devices, the amplification system allows a precise power for the amplified signal, even in a harsh environment. The harsh environment translates into two phenomena:
The mobility of the radio station, causing load variations for the amplifier.

Moreover, this load variation added to the mismatch between the antenna and the amplifier brings about large variations in the gain of the amplifier and in the incidental power.
Operation with a co-site jammer, that is to say with a transmitter close by.

This system allows continuous slaving of waveforms with a non-constant envelope making it possible to use linearization techniques. The reason is that the use of a linearization technique requires perfect control of the gain of the chain because the non-linearities can be corrected only for small variations around the operating point. Thus, linearization by pre-distortion requires a model of the amplifier. This model is valid for a precise operating point notably characterized by the mean transmission power, transmission frequency and temperature.

In one embodiment, the use of a mixer associated with the anti-jamming device makes power servo control possible in a co-site situation (This situation is realized when various radio systems are situated in a close geographical region. This geographical region is defined by a circle having a radius in the order of ten or so metres). Moreover, the use of a mixer (which has a linear voltage response) rather than a logarithmic detector facilitates servo control because it is no longer necessary to use conversion tables. These conversion tables allow an item of information of logarithmic type to be converted into an item of information of linear type.

### BRIEF DESCRIPTION OF THE DRAWINGS

The invention will be better understood and other advantages will emerge upon reading the detailed description provided by way of non-limiting example and with reference to the figures, in which:

FIG. 1 shows a system according to the prior art.

FIG. 2 shows the system using the method of the invention.

FIG. 3 shows the voltage-controlled variable attenuator.

FIGS. 4.a to 4.c show the model of perturbation of the signal by the amplification device.

FIG. 4d shows the voltage-controlled variable attenuator.

FIG. 5 shows the system using a conversion table.

FIG. 6 shows the method for using the system.

FIG. 7 shows the various phases of use of an FH signal.

FIG. 8 shows a mode of implementation of the system.

### DETAILED DESCRIPTION

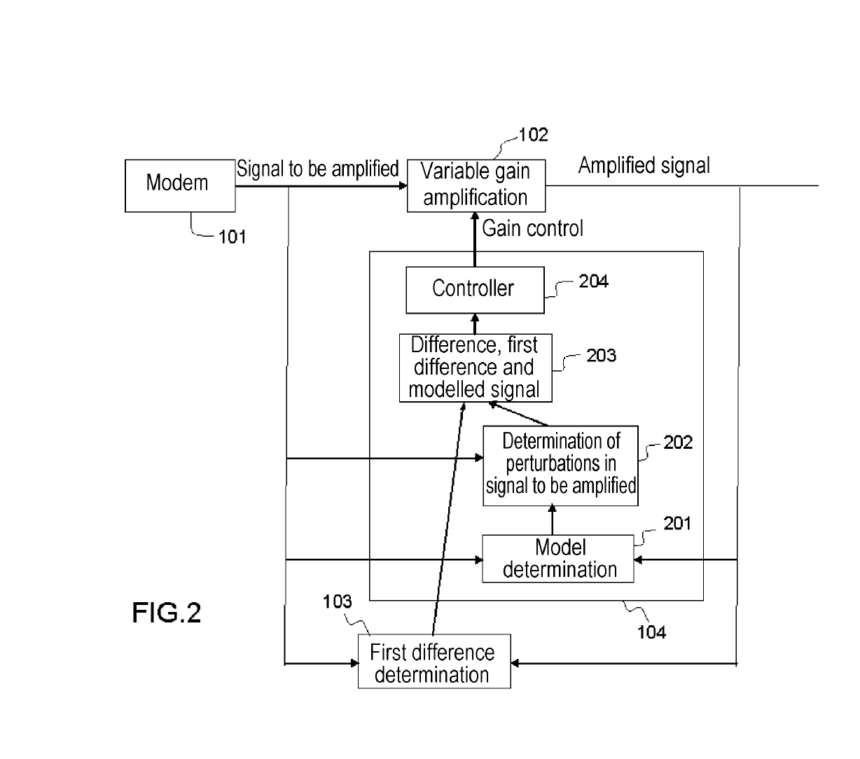

FIG. 2 describes the system according to a first aspect of the invention. In this embodiment, the modem 101 is connected to the amplification system. The amplification system has:
a device 102 for amplifying the signal transmitted by the modem. This amplification device 102 exhibits a variable gain,
a first device 103 for determining a first difference between the signal amplified by the device 102 and the signal to be amplified that is delivered by the modem 101,
a second device 104 for determining the variable gain of the amplification device 102.

The second device 104 for determining the variable gain effects this determination on the basis of:
the difference calculated by the first determination device 103,
the signal to be amplified that is transmitted by the modem 102 and
the signal amplified by the amplification device 102.

This second device has:
a third determination device 201 for determination of a model of the perturbation of the first difference by the amplification device and possibly the extraction device 301 (this determination of the model is implemented on the basis of the signal to be amplified and the amplified signal),
a fourth determination device 202 for determination of the perturbation of the first difference using the signal to be amplified and the model obtained by the third device 201,
a fifth determination device 203 for determination of a second difference between the first difference, obtained by the first device, and the perturbation determined by the fourth device, and
a controller 204 that is capable of determining the variable gain on the basis of the second difference.

In an embodiment that is shown in FIG. 3, the system has an extraction device 301 for extraction of the amplified signal to the first device for determining a difference.

This extraction device 301 comprises:
a directional coupler 302 that allows recovery of the signal transmitted on a wire connecting the amplification device 102 and the transmission antenna,
at least one device 303 for regulating the gain of the recovered signal,
an analogue mixer 304, which allows mixing of the signal that has had its gain regulated by the device for regulating the gain with a sinusoidal signal, the sinusoidal signal being the local oscillator that is shared between the transmission mixer and the mixer of the measurement path in order to ensure coherence between the phase of the transmitted signal and the phase of the received signal,
and a plurality of filters 305 that are suited to filtering the mixed signal.

These filters can be used to implement an anti-jamming function, and they are then suited to the signal to be amplified and to the frequency disparity between the signal to be amplified and the jamming signal. The invention may include several types of filters:
a fixed-bandwidth analogue filter used for anti-aliasing and anti-jamming, and
several variable-bandwidth switchable digital filters. The configuration of the digital filters is implemented as a function of the bandwidth of the signal to be transmitted and of the anticipated frequency disparity of the jamming signal.

In one embodiment, the model of perturbations of the signal to be amplified, which are caused by the amplification device and the extraction device 301, has a pure delay and a gain.

The third device 201 uses a correlator of difference amplitude type that works in non-real time during the start of use of the automatic gain controller. In order to determine the value of this delay and of this gain, the third device uses the correlation function R(m) between the signal to be amplified X(n) and the amplified signal z(n). This correlation is expressed using the following relationship:

$$R ( m ) = {\sum }_{n = 0}^{N} D [ x ( n ) ] * D [ z ( n + m ) ] m ∈ [ - N , N ]$$

$$D [ x ( n ) ] = sign [ \vert x ( n ) \vert - \vert x ( n - 1 ) \vert ]$$

$$sign ( d ) = \{ \begin{matrix}1 & d > 0 \\ 0 & d = 0 \\ - 1 & d < 0\end{matrix}$$

The determination of the perturbation model produces an estimate mean_g of the total mean gain and Tg of the total pure delay of the loop (these values are dependent on the number of samples).
Tg is given by the index m of the maximum value of the function R(m)
mean_g is the mean value of the instantaneous gain between the signal received on the measurement path sig_out and the transmitted and delayed signal of Tg sig_in_del.

$$mean\_g = mean ( G\_inst ) = mean ( \frac{{abs ( sig\_out ( n ) )}^{2}}{{abs ( sig\_in \_del ( n ) )}^{2}} )$$

The value of mean_g is corrected by the value of the variable gain (the gain of the voltage-controlled variable attenuator denoted by the acronym GWA) to give an estimate of the static gain G_stat.
The determination device 202 for determination of the perturbation of the first difference adapts the operation of a Smith predictor to the case of a modulated signal which, in association with a pure delay of the radio channel, causes a perturbation of the error signal.
The device 202 determines the perturbation signal S_{corr}(n) by virtue of the following formula:

S_{corr}(n)=GVVA(n)*G_stat*(abs(sig_{—}in_{—}del(n)²))

where:
sig_in represents the modulated input signal,
sig_in_del represents the modulated input signal delayed by Tg,
GVVA(n) is the modelled gain of the variable attenuator,
G_stat is a static gain determined on the basis of mean_g, the setpoint gain and the mean value of GVVA over the duration necessary for correlation:

Gₛₜₐₜ=mean_{—}g/mean(GVVA)
GVVA(n)*G_stat*(abs(sig_in(n))² is an undelayed term
GVVA(n)*G_stat*(abs(sigin_del(n))² is a term delayed by Tg
   The signal S_{corr}(n) is subtracted from the main error signal Error(n) that come from the device 103 for determining the first difference. This new device is the device 203 for determining the corrected error signal E_corr(n), therefore:

E_corr(n)=Error(n)−S_{corr}(n)

It is known from the prior art that the Smith predictor operates in the following manner:
The Smith predictor technique allows elimination of the contribution of the group time in the servo control by modifying the closed-looped transfer function.
A second loop is added to the main looped system. This loop uses a model of the transfer function downstream of the PID controller and allows the main error signal to be corrected:

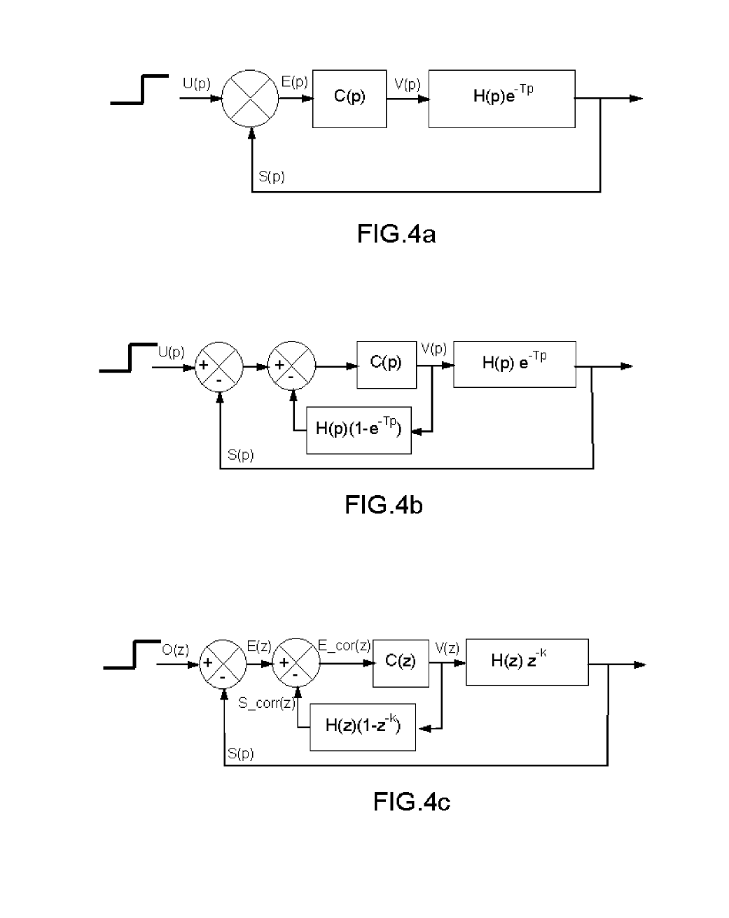

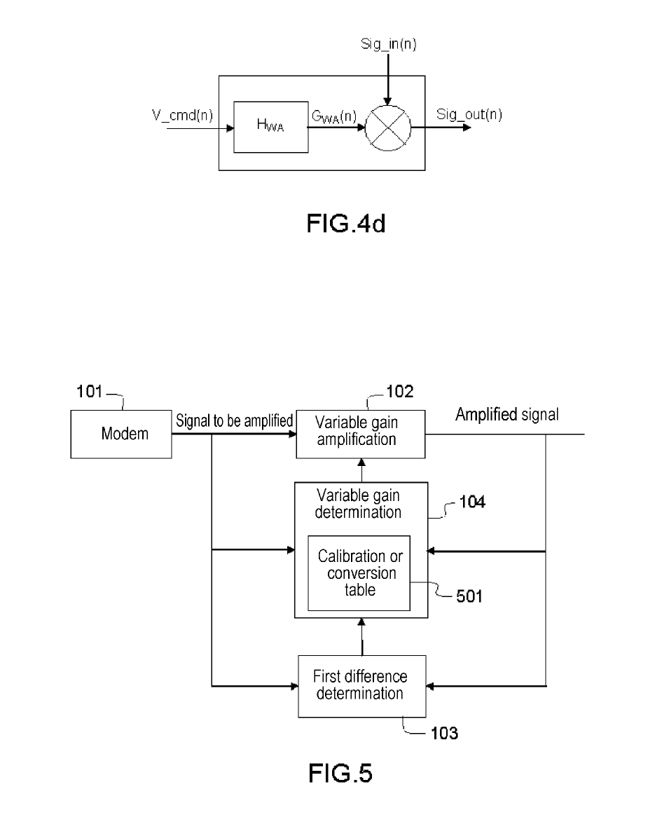

FIG. 4.ashows a classic example of a looped system having a delay. In this system, the transfer function C(p) corresponds to a controller. The transfer function H(p)e^{-Tp} corresponds to the rest of the loop. In the case of the present invention, it is likened to the set made up of the transmission path and the measurement path.

The open-looped transfer function (OLTF) of a looped system without a pure delay is expressed by:

OLTF′=c(p)*H(p)

The closed-looped transfer function (CLTF) of a looped system without a pure delay is expressed by:

$${CLTF}^{′} = \frac{{OLTF}^{′}}{1 - {OLTF}^{′}}$$

$${CLTF}^{′} = \frac{C ( p ) * H ( p )}{1 + C ( p ) * H ( p )}$$

The open-looped transfer function (OLTF) of a looped system with a pure delay is expressed by:

OLTF=c(p)*H(p)e^{-Tp}

The closed-looped transfer function (CLTF) of a looped system with a pure delay is expressed by:

$$CLTF = \frac{OLTF}{1 - OLTF}$$

$$CLTF = \frac{C ( p ) * H ( p ) {e}^{- Tp}}{1 + C ( p ) * H ( p ) {e}^{- Tp}}$$

It is noticeable that the pure delay appears in the denominator, which does not allow an unconditional stability to be obtained whatever the value of the pure delay.

To compensate for this problem, it is possible to synthesize a new controller C′(p) allowing the delay in the denominator of the function CLTF to be eliminated.

This requires calculation of the transfer function CLTF″ with the new controller C′(p), which will be equal to:

$${CLTFF}^{″} = \frac{{C}^{′} ( p ) * H ( p ) {e}^{- Tp}}{1 + {C}^{′} ( p ) * H ( p ) {e}^{- Tp}} = {CLTF}^{′} * {e}^{- Tp}$$

The following is then obtained:

$$\frac{{C}^{′} ( p ) * H ( p ) {e}^{- Tp}}{1 + {C}^{′} ( p ) * H ( p ) {e}^{- Tp}} = \frac{C ( p ) * H ( p ) {e}^{- Tp}}{1 + C ( p ) * H ( p )}$$

By solving the equation above, the expression for the new controller C′(p) is obtained:

$${C}^{′} ( p ) = \frac{C ( p )}{1 + C ( p ) * H ( p ) * ( 1 - {e}^{- Tp} )}$$

FIG. 4.b illustrates the new loop thus formed.

FIG. 4.c shows this loop in the digital domain.

In this FIG. 4.c, the secondary loop implements the transfer function:

H(z)(1−z^{-k})

The main error signal E(z) is subtracted from the output signal of the Smith predictor S_{corr}(z)to produce a corrected error E_corr(z).

E_cor(n)=Error(n)−Scorr(n)

The signal E_cor(z) is sent to the transfer function controller C(z).
The signal S_corr generated by the fourth device 203 for determining the corrected error by virtue of the following relationship

S_{corr}(n)=GVVA(n)*G_stat*(abs(sig_{—}in(n))²−abs(sig_{—}in_{—}del(n)²))

is a generalization of the Smith predictor technique in the case of a downstream transfer function H(z) including the contribution of the modulated samples.

The formula H(z)(1−z^{-k}) can be broken down as follows:
Undelayed downstream transfer function: H(z)
Delayed downstream transfer function H(z)z^{-k}
   It is possible to identify the delayed and undelayed terms of the following formula:

S_{corr}(n)=GVVA(n)*G_stat*(abs(sig_{—}in(n))²−abs(sig_{—}in_{—}del(n)²))

using the delayed and undelayed terms of the formula from the Smith predictor:
H(z) corresponds to GVVA(n)*G_stat*abs(sig_in(n))²
H(z)^{-k} corresponds to GVVA(n)*G_stat*abs(sig_in_del(n))²
   The term GVVA(n)*G_stat*abs(sig_in_del(n))² models the variable attenuator, the amplifier and the measurement path. These elements are considered to be linear and are “contained” in the delay and the static gain (Tg and G_stat). In order to obtain the gain GVVA, it is necessary to model the voltage-controlled variable attenuator.

The variable attenuator is modelled as a voltage-controlled variable gain or a system having two inputs and one output. FIG. 4.d shows the model of this attenuator. The gain response GVVA of the voltage-controlled attenuator is modelled by a 2nd-order transfer function associated with a pure delay and with an offset. This transfer function is set up on the basis of measurements from a component targeted to implement the automatic gain control function.

The transfer function HVVA(p) is identified on the basis of measurement and takes the following form:

$$HVVA ( p ) = \frac{{GVVA}_{0} ( p )}{V\_cmd ( p )} = \frac{Katt * {e}^{- Tatt * p}}{( 1 + τ a tt * {p}^{2} )} + off\_att$$

This relationship allows the gain of the attenuator to be modelled by a second-order low-pass transfer function associated with a pure delay.
V_cmd(p) represents the control voltage of the attenuator.
GVVA₀(p) represents the modelled gain of the attenuator.
Katt represents the gain of the attenuator.
e^{-Tatt*p} represents the pure delay of the attenuator vis-à-vis its control voltage.
1+ratt*p² represents the denominator of a 2nd-order low-pass function.
off_att represents the gain offset, thus when the control voltage is zero the gain is not zero. This offset allows the attenuation dynamics of the component to be modelled, which are limited.
Transposition of the polynomial portion of the transfer function HVVA(p) to the digital domain by bilinear transformation.
Modelling of the pure delay e^{-Tatt*p} by an all-pass filter of Thiran filter type. The Thiran filter T(z) is a known approximation allowing synthesization of a delay that is fractional in relation to the sampling period. The transfer function of the Thiran filter is given by the following equation:

T(z)=z^{-N}D(z⁻)/D(z)

D(z)=1+a₁z⁻¹+ . . . +a_{N}z^{-N}

The coefficients of the filter are calculated by virtue of the following equation:

$${a}_{k} = {( - 1 )}^{k} ( \begin{matrix}N \\ k\end{matrix} ) {\prod }_{n = 0}^{N} \frac{d + n}{d + k + n}$$

N=ceil(D),
where D=Tg*Fs
Fs represents the sampling frequency,
d=D−N.
Finally, the final transfer function in the digital domain HVVA(z) is obtained by performing convolution of the primary transfer functions. The final transfer function HVVAt(z) is the product of the bilinear transform (in the domain z) of the transfer function HVVA(p) and the transfer function of the Thiran filter T(z).

HVVAt(z)=HVVA(zz)*T(z)
If the discrete samples for the two filters are considered, this amounts to obtaining the product of convolution between the samples from the two filters HVVA(n) and T(n).

The infinite impulse response filter, representing HVVAt(z), thus obtained is, in a non-limiting embodiment, of 6th-order (convolution of a 2nd-order filter and of a 3rd-order filter for the delay).

In order to model the non-linearity of the attenuator and of the transmission chain, the samples GVVA₀(n) from the filter HVVA(z) are multiplied by a polynomial function.
The polynomial function is applied directly to the samples GVVA₀(n) in order to obtain the gain GVVA(n) by virtue of the following formula:

$$GVVA ( n ) = {\sum }_{k = 0}^{K} ak {GVVA}_{0}^{k}$$

FIG. 5 describes the system in which the second determination device 104 has a conversion table 501 that allows a power of said signal to be transmitted to be related to the amplification gain.

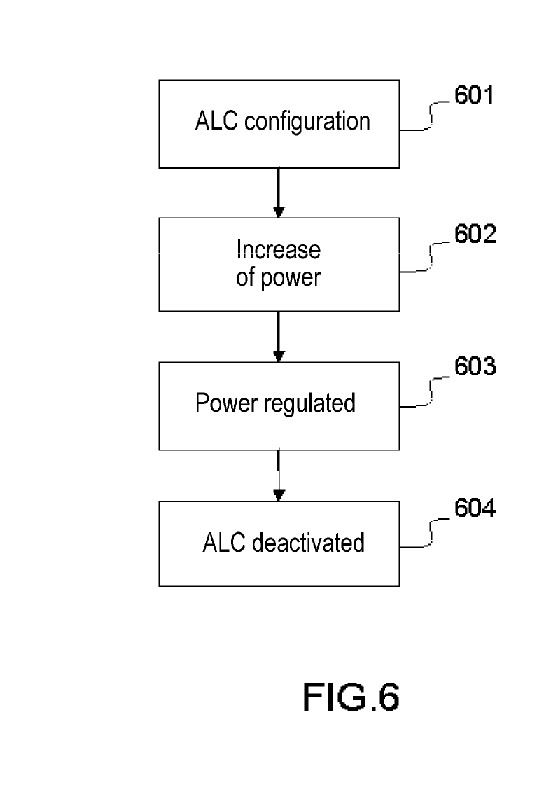

FIG. 6 describes a first embodiment of the method for implementing the system described in this invention. This method has the following steps:
a step 601 of configuration of the gain of the amplification device, this step of configuration being carried out when the amplified signal has zero power,
a step 602 of increase of the amplification gain of the amplification device,
a step 603 of regulation of the amplification gain of the amplification device. The regulation scheme is obtained at the end of the time required by the estimator to update the gain and delay parameters (mean_g and Tg) of the device for correcting the error.
a step 604 of deactivation of the regulation of the gain, this step of deactivation being carried out when the signal to be amplified has useful data.

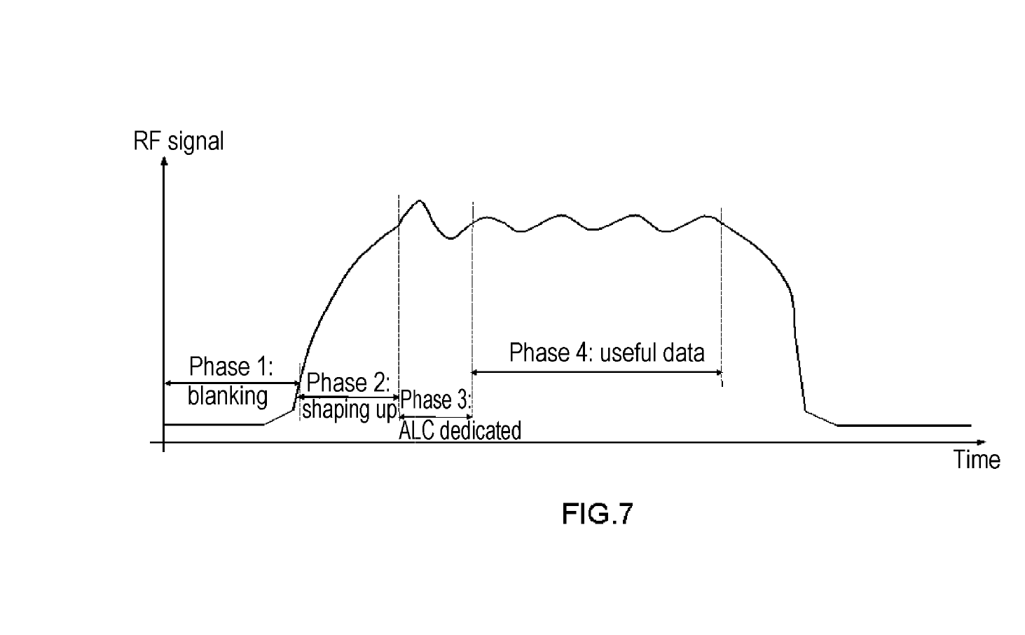

Thus, when the system is used to amplify signals exhibiting rapid variations in the modulation frequency (these signals are also known by the expression FH—for Frequency Hopping—signals), four distinct operating phases are present. These phases are shown in FIG. 7 and are the following phases:
A first phase, called “blanking” phase. During this phase, the power of the signal is zeroed. Thus, no signal is transmitted by the antenna. This phase is also called “bearing hole” and it is used to implement the configuration of the various devices of a radio (frequency positioning and routing of the switches, notably). This time is used to implement step 601 of configuration of the gain of the amplification device. This is realized, in one embodiment, by using the following relationship:

Pout_max=Pout_mean_MODEM_setpoint+Modulation_crest_factor

in this relationship;
Pout_max represents the maximum output power,
Pout_mean_Modem_setpoint represents the average power of the signal that the modem will transmit, and
Modulation_crest_factor represents the crest factor of the modulation of the signal that will be transmitted by the MODEM.
Moreover, during the step of configuration 601, the amplification device 102 is configured to allow the transmission of a signal of maximum power Pout_max.
The determination of Pout_max by means of this calculation allows configuration of the gain to be applied to the setpoint signal (setpoint gain) so as to compare it with the signal received on the measurement path. On the basis of the value of Pout_max, calibration tables for the measurement path are addressed. These contain the values of the setpoint gain and the configuration of the variable-gain elements of the measurement path corresponding to the power Pout_max.
A second phase called “shaping” phase, this phase allowing the rise in power of the transmitted signal. The quality of the rise in power is very high because it influences the width of the spectrum of the signal transmitted by the antenna. This phase is implemented via step 602 of increase of the amplification gain of the amplification device. In an illustrative embodiment, this step can be carried out by the configuration of the second determination device 104 so that they use the conversion table 401 when the power of said signal to be amplified is lower than a threshold, and via the configuration of the second determination device 104 so as to use the controller 204 when the power of the signal to be amplified is higher than this threshold. This threshold is variable and is fixed by configuration. It is dependent on the power of the jamming signal expected on the measurement path. In one embodiment, this threshold has a typical value of between −20 dB and −5 dB with a preferential value of −15 dB.
Let S/J be the ratio between the power of the useful signal and the maximum power expected from the jamming signal on the measurement path after the anti-jamming filters. The trigger threshold then has the following value:

Threshold=S/J(dB)−10 dB.
A third phase called “ALC dedicated” phase, the phase during which all of the processing operations necessary for regulating the gain of the amplification device need to be carried out. The duration of this phase may be variable. During this phase, step 603 of regulation is used. During this step of regulation 603, the setpoint gain used is that determined during step 601 of configuration using the relationship

Pout_max=Pout_mean_MODEM_setpoint+Modulation_crest_factor
and the calibration tables.
Finally, the fourth phase corresponds to the phase of sending the useful data. In one embodiment, the gain of the amplification device must be stabilized at the beginning of this phase and cannot then evolve again. This phase corresponds to step 604 of deactivation of the regulation of the gain.

When the waveform operates in continuous mode, step 603 of regulation of the gain is not realized explicitly. The amplification system must therefore be capable of regulating the gain without degrading the useful data.

However, in the case in which a continuous waveform explicitly anticipates a phase dedicated to automatic gain control, the operation of the amplification system is identical to FH operation with, moreover, transitions from step 604 of deactivation of the regulation to step 603 of regulation of the gain. In this case, the time interval during which step 603 of regulation of the gain is carried out needs to be signalled to the gain control device so that it is able to adapt the model of perturbations. This interval must be compatible with the determination carried out by the determination device 201 for determination of the model.

In one embodiment, the modem and the amplification system exchange a certain number of parameters that are representative of the waveform that needs to be amplified. These parameters can be exchanged at the moment at which the waveform is loaded or during the use of the waveform and include:
The RMS output power (dBm) desired at the output of the amplifier
The crest factor for the modulation (dB) of the signal to be amplified
The modulation bandwidth (Hz) of the amplified signal
The transmission frequency.

The bandwidth information allows addressing of the tables containing the parameters of the regulation loop, notably the coefficients of the P controller (integration constant, gain) and of the digital filters of the measurement path.

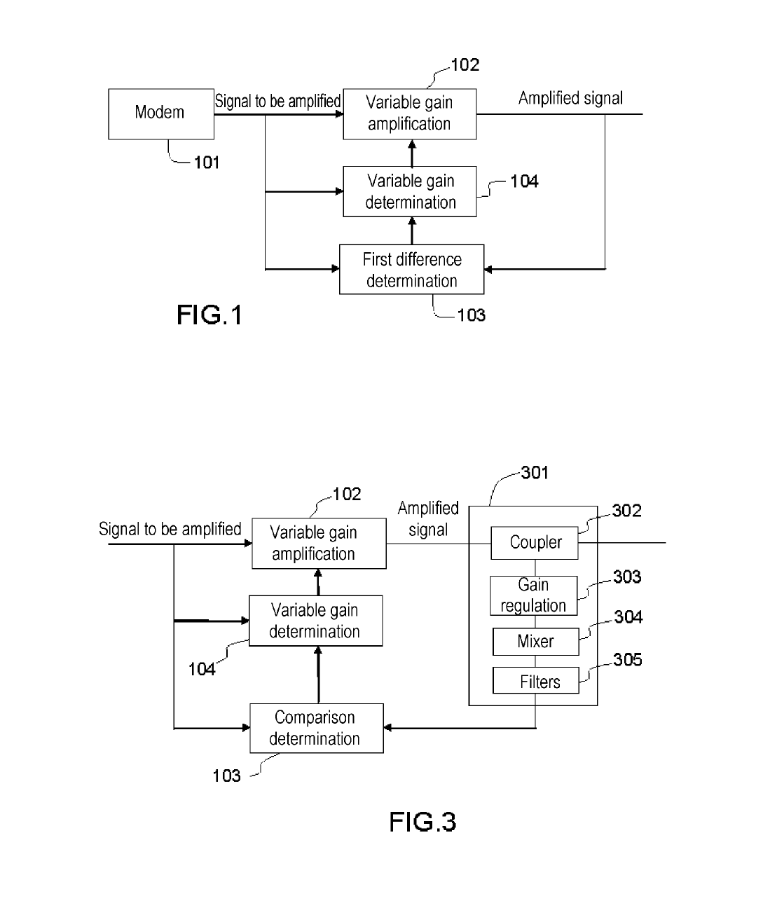

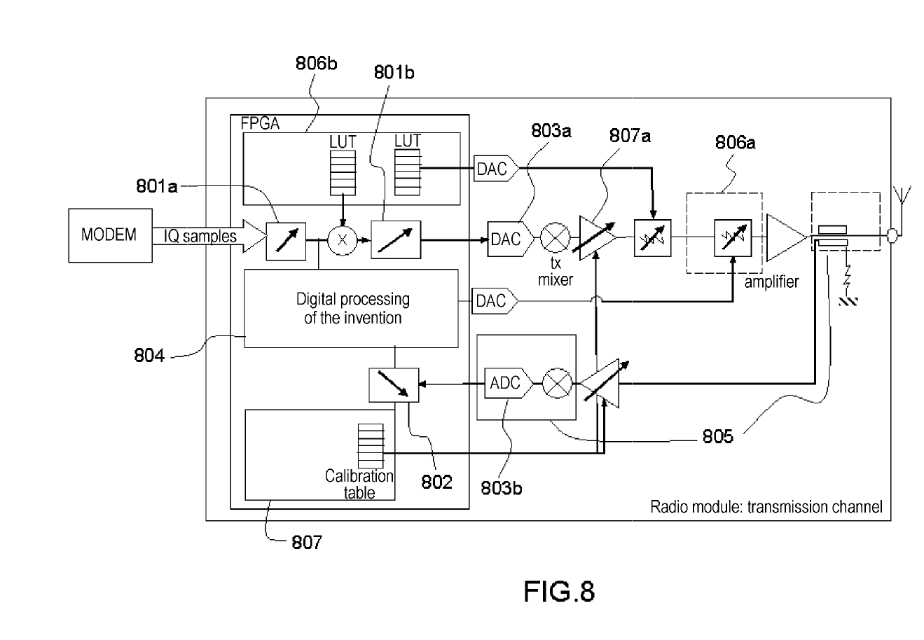

FIG. 8 shows a mode of implementation of the system of the invention. In this implementation, the system comprises the following elements:
DUC (Digital Up Converter) filters that allow conversion of the signal from a base frequency to an intermediate frequency. In FIG. 8, these filters are referenced 801.a and 801.b.
A DDC (Digital Down Converter) filter that allows conversion of the signal from an intermediate frequency to a base frequency. In FIG. 8 this filter is referenced 802.
Two digital-to-analogue converters (known also by the expression DAC) that are referenced 803.a and 803.b in FIG. 8.
A digital processing portion of the invention that is referenced 804 in FIG. 8. This digital processing portion of the invention (made up of the main loop and the predictive control loop) needs to be implemented between the chain of digital processing for the modulated samples transmitted and the digital-to-analogue converter of the transmission path. This portion corresponds to elements 103 and 104 in FIG. 1 or 3.
A frequency-selective detection portion that is referenced 805 in FIG. 8. This frequency-selective detection portion needs to be realized by a directional coupler arranged between the output of the power amplifier and the antenna, a gain regulation device, a mixer, an analogue-to-digital converter and a set of analogue and digital filters distributed along the detection chain. A gain pre-positioning system is likewise used in the detection path so as to make the gain of the loop almost constant for a large range of operating power (in the order of 25 dB), thus facilitating the stability of the main loop. This portion corresponds to elements 302, 303, 304 and 305 in FIG. 3.
The invention implements two open-loop gain controls referenced 806.a and 806.b, intended for the bearing shaping (during the “shaping” phase) by means of a plurality of conversion tables using static coefficients (LUT), a digital gain arranged in the chain of digital processing for the transmitted signal and a voltage-controlled analogue attenuator with a digital-to-analogue converter. These controls are integrated in the second determination device 104.
The invention implements closed-loop gain control using the two digital processing loops claimed in the invention and a voltage-controlled analogue attenuator with a digital-to-analogue converter. This control is integrated in the second determination device 104.
The algorithm for the method of the invention is suited more particularly to waveforms of FH type but can easily be suited to waveforms of continuous type because it has a regulation mode allowing it to be activated during the useful phase of the modulation.
The system also has a device 807 for repositioning the static gains 807.a and the gain of the gain regulation device 303 that uses a calibration table.

1. An amplification system, connected to a modem delivering a signal to be amplified, comprising:
at least one amplification device in which an amplification gain is variable,
at least one first determination device for determination of a first difference between an amplified signal and said signal to be amplified,
at least one second determination device for determination of said variable gain,
wherein said second determination device is capable of the determination of said variable gain on the basis of said signal to be amplified, said amplified signal and said first difference;
said second device having:
at least one third determination device for determination of a model, comprising a delay and a gain, of the perturbation of the first difference by the amplification device by means of a correlation between said signal to be amplified and said amplified signal,
at least one fourth determination device for determination of perturbations of the first difference that are caused by said amplification device, on the basis of said model and said signal to be amplified,
at least one fifth determination device for determination of a second difference between said first difference and said perturbations, and
a controller that is capable of determining said variable gain on the basis of said second difference.

2. The amplification system of claim 1, having at least one extraction device, for extraction of said amplified signal to said first determination device, wherein said extraction device comprises:
a directional coupler that is used to recover the signal transmitted on a wire connecting said amplification device and an antenna,
at least one device for regulating the gain of the recovered signal,
a mixer for mixing the signal that has had its gain regulated with a sinusoidal signal, and
a plurality of filters for filtering the mixed signal, said filters comprising at least one fixed-bandwidth analogue filter that is used for anti-aliasing and/or anti-jamming and at least one switchable digital filter for the bandwidth that varies as a function of a bandwidth of said signal to be amplified and/or of a disparity between a frequency of said signal to be amplified and a frequency of said perturbations, and
said third device is suited further to the determination of a model of the perturbation of the first difference by said amplification device and said extraction device.

3. The amplification system of claim 1, wherein said first determination device is connected directly to said modem.

4. The amplification system of claim 1, wherein said controller is a PID controller.

5. The amplification system of claim 1, wherein said second determination device has a conversion table relating a power of said signal to be transmitted to said amplification gain.

6. A method for using the amplification system of claim 1, wherein the method comprises the successive steps of:
a step of configuration of the gain of said amplification device, said step of configuration being carried out when said signal to be amplified has zero power,
a step of increase of the amplification gain of the amplification device, in an initialization phase, during which said signal to be amplified does not have any useful data,
a step of deactivation of the regulation of the gain, said step of deactivation being carried out when the signal to be amplified has useful data.

7. The method of claim 6, further comprising
a step of regulation of the amplification gain of the amplification device, said step) of regulation of the amplification gain being carried out after said step of increase of the amplification gain, moreover said step of regulation being carried out on the basis of a setpoint.

8. The method of claim 6, in which said step of configuration is suited to the implementation of the relationship:
Pout_max=Pout_mean_MODEM_setpoint+Modulation_crest_factor
where
Pout_max represents the maximum output power in dB,
Pout_mean_MODEM_setpoint represents the mean power in dB of the signal that said modem will transmit, and
Modulation_crest_factor represents the modulation crest factor in dB of the signal that will be transmitted by said modem,
and in which the step of configuration is suited to configuring said amplification device so as to be able to transmit a maximum output power of Pout_max.

9. The method of claim 6, wherein said step of increase of the amplification gain is implemented:
by means of a conversion table relating a power of said signal to be transmitted to said amplification gain when the power of said signal to be amplified is lower than a threshold; and
by means of said controller when the power of said signal to be amplified is higher than said threshold.
